(19) United States
(12) Patent Application Publication
(10) Pub. No.: US 2026/0194933 A1
(43) Pub. Date: Jul. 9, 2026

(54) SENSOR DEVICE AND DISPLAY APPARATUS INCLUDING THE SAME

(71) Applicant: SAMSUNG ELECTRONICS CO., LTD., Suwon-si (KR)

(72) Inventors: Sunghwan Park, Suwon-si (KR); Moah Park, Suwon-si (KR); Hakyoung Kim, Suwon-si (KR); Jaebum Ko, Suwon-si (KR); Giyoung Go, Suwon-si (KR)

(73) Assignee: SAMSUNG ELECTRONICS CO., LTD., Suwon-si (KR)

(21) Appl. No.: 19/456,561

(22) Filed: Jan. 22, 2026

Related U.S. Application Data
(63) Continuation of application No. PCT/KR2025/022951, filed on Dec. 29, 2025.

(30) Foreign Application Priority Data
Jan. 6, 2025 (KR) 10-2025-0001781

(51) Int. Cl. G06F 1/16; H05K 5/02; H05K 5/03

(52) U.S. Cl. CPC G06F 1/1601; H05K 5/0243; H05K 5/03

(57) ABSTRACT

Provided is a display apparatus including a case, a display panel mounted to the case, and a sensor device including a fixing member fixed inside the case and a moving member movably provided with respect to the fixing member and on which at least one sensor is mounted. When a detachable bezel is detached from the case, the moving member is positioned at a first position, and when the detachable bezel is mounted to the case, the moving member is positioned at a second position by being moved by a magnetic force.

### CROSS-REFERENCE TO RELATED APPLICATION(S

This application is a continuation application of International Application No. PCT/KR2025/022951, filed December 29, 2025, which claims priority from Korean Patent Application No. 10-2025-0001781, filed on January 6, 2025 in the Korean Intellectual Property Office, the disclosures of which are herein incorporated by reference in their entireties.

### BACKGROUND

### 1. Field

The present disclosure relates to a sensor device and a display apparatus including the same.

### 2. Description of Related Art

A display apparatus is an output device that visually presents acquired or stored image information to a user, and is used in various areas such as a home, a business, and/or the like.

In display apparatuses, a display panel for displaying content is gradually becoming larger. In addition, a case that covers the edge and the rear surface of the display panel in the display apparatus is also becoming thinner. The display apparatus enhances a user’s sense of immersion in the image by decreasing the thickness of a bezel.

The display apparatus may be provided with a decorative bezel detachably mounted to the case to cover a portion in which the decorative bezel is disposed, while also improving design according to a user’s preference.

The display apparatus may further include a sensor for receiving a signal transmitted from an input device such as a remote controller, an illuminance sensor for detecting the brightness around the display apparatus, a color sensor for detecting color, and a motion sensor for detecting a user’s movement.

### SUMMARY

One aspect of the present disclosure provides a display apparatus capable of receiving a signal from an input device, detecting ambient brightness and color, and detecting a user’s movement, even when a decorative bezel is mounted.

Another aspect of the present disclosure provides a sensor device capable of automatically changing a position of a sensor without a separate operation when a decorative bezel is mounted, and a display apparatus including the same.

Another aspect of the present disclosure provides a sensor device capable of automatically changing the position of a sensor using a magnetic force of a magnet when a decorative bezel is mounted, and a display apparatus including the same.

The technical objectives of the present invention are not limited to the above, and other objectives that are not described above will be clearly understood by those skilled in the art from the above detailed description.

A display apparatus according to an aspect of an example embodiment of the disclosure may include: a case; a display panel mounted to the case; and a sensor device including a fixing member fixed inside the case and a moving member movably provided with respect to the fixing member and on which at least one sensor is mounted. When the detachable bezel is detached from the case, the moving member is positioned at a first position, and when the detachable bezel is mounted to the case, the moving member is positioned at a second position by being moved by a magnetic force.

A sensor device according to an aspect of an example embodiment of the disclosure may be included in a display apparatus including a display panel, the sensor device including: a moving member on which at least one sensor is mounted; and an elastic member configured to bias the moving member to a first position in a direction toward the display panel, wherein the moving member includes at least one of a magnet or metal and is configured to move between the first position and a second position away from the display panel by a magnetic force generated from the at least one of the magnet or metal and an elastic force of the elastic member.

A sensor device according to an aspect of an example embodiment of the disclosure may be included in a display apparatus including a display panel, the sensor device including: a fixing member fixed at a portion of the display apparatus; and a moving member on which at least one sensor is mounted and configured to move with respect to the fixing member by a magnetic force, the moving member including at least one of a magnet or metal, wherein the moving member is configured to, when a detachable bezel is mounted to the display apparatus, move in a direction away from the display panel such that the at least one sensor protrudes from the detachable bezel.

### BRIEF DESCRIPTION OF DRAWINGS

The above and other aspects, features, and advantages of certain embodiments of the disclosure will be more apparent from the following description taken in conjunction with the accompanying drawings.

FIG. 1 illustrates a display apparatus according to one or more embodiments.

FIG. 2 illustrates a display apparatus according to an embodiment, with a decorative bezel removed.

FIG. 3 is an exploded view of a display apparatus according to an embodiment.

FIG. 4 is a view of FIG. 3 seen from a different angle

FIG. 5 is an enlarged front view of portion B of FIG. 2.

FIG. 6 is an enlarged front view of portion A of FIG. 1.

FIG. 7 is an enlarged view of a sensor device shown at portion C of FIG. 4.

FIG. 8 is an exploded view of the sensor device of FIG. 7.

FIG. 9 is an enlarged view of a portion of a rear surface of a display apparatus according to an embodiment, illustrating a moving member of a sensor device positioned at a first position.

FIG. 10 is an enlarged view of a portion of a rear surface of a display apparatus according to an embodiment, illustrating a moving member of a sensor device positioned at a second position.

FIG. 11 is a cross-sectional view taken along line D-D’ of FIG. 9.

FIG. 12 is a cross-sectional view taken along line E-E’ of FIG. 10.

FIG. 13 illustrates a sensor device of a display apparatus according to an embodiment.

### DETAILED DESCRIPTION

The example embodiments described in the disclosure and the configurations shown in the drawings are only examples of the disclosure, and various modifications may be made at the time of filing of the disclosure to replace the embodiments and drawings of the disclosure.

In the description of the drawings, like numbers refer to like elements throughout the description of the drawings.

The singular form of a noun corresponding to an item may include one or a plurality of the items unless clearly indicated otherwise in a related context.

In this document, phrases, such as “A or B”, “at least one of A and B”, “at least one of A or B,” “A, B or C,” “at least one of A, B and C,” and “at least one of A, B, or C”, may include any one or all possible combinations of items listed together in the corresponding phrase among the phrases.

The terms of “~part”, “~module” and “~member” may be implemented in hardware or software. In some embodiments, a plurality of “~parts”, “~modules” and “~members” may be implemented as a single component. In some embodiments, a single “~part”, “~module” and “~member” may include a plurality of components.

The terms used herein are for the purpose of describing the embodiments and are not intended to restrict and/or to limit the disclosure. The singular expressions herein may include plural expressions, unless the context clearly dictates otherwise. In addition, the terms “comprises”, “includes”, and “has” are intended to indicate that there are features, numbers, steps, operations, elements, parts, or combinations thereof described in the specification, and do not exclude the presence or addition of one or more other features, numbers, steps, operations, elements, parts, or combinations thereof.

It will be understood that, although the terms first, second, etc. used in the disclosure may be used herein to describe various components, these components should not be limited by these terms. These terms are only used to distinguish one component from another. For example, a first element could be termed a second element, and similarly, a second element could be termed a first element without departing from the scope of the disclosure. The term “and/or” includes combinations of one or all of a plurality of associated listed items.

When one (e.g., a first) element is referred to as being “coupled” or “connected” to another (e.g., a second) element with or without the term “functionally” or “communicatively,” it means that the one element is connected to the other element directly, wirelessly, or via a third element.

It will be understood that when a certain component is referred to as being “connected to”, “coupled to”, “supported by” or “in contact with” another component, it may be directly or indirectly connected to, coupled to, supported by, or in contact with the other component. When a component is indirectly connected to, coupled to, supported by, or in contact with another component, it may be connected to, coupled to, supported by, or in contact with the other component through a third component.

It will also be understood that when a component is referred to as being “on” another component, it may be directly on the other component or intervening components may also be present.

Meanwhile, the terms “up-and-down direction,” “front-rear direction,” and/or the like used in the following description are defined with reference to the drawings, and the shapes and positions of the respective components are not limited by these terms.

For example, the terms “front” and “rear” may refer to the +X direction and the –X direction shown in the drawings, respectively. The terms “upward” and “downward” may refer to the +Z direction and the –Z direction shown in the drawings, respectively. The terms “left direction” and “right direction” may refer to the +Y direction and the –Y direction shown in the drawings, respectively. The term “vertical direction” may refer to the Z direction shown in the drawings, and the term “horizontal direction” may refer to the Y direction shown in the drawings

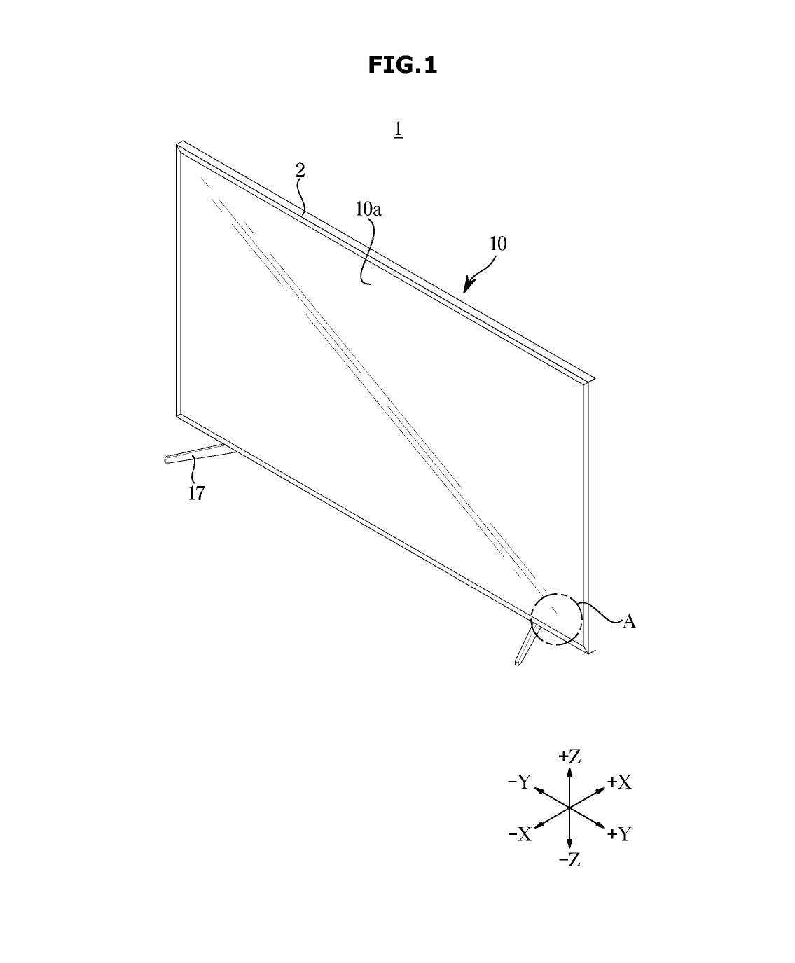

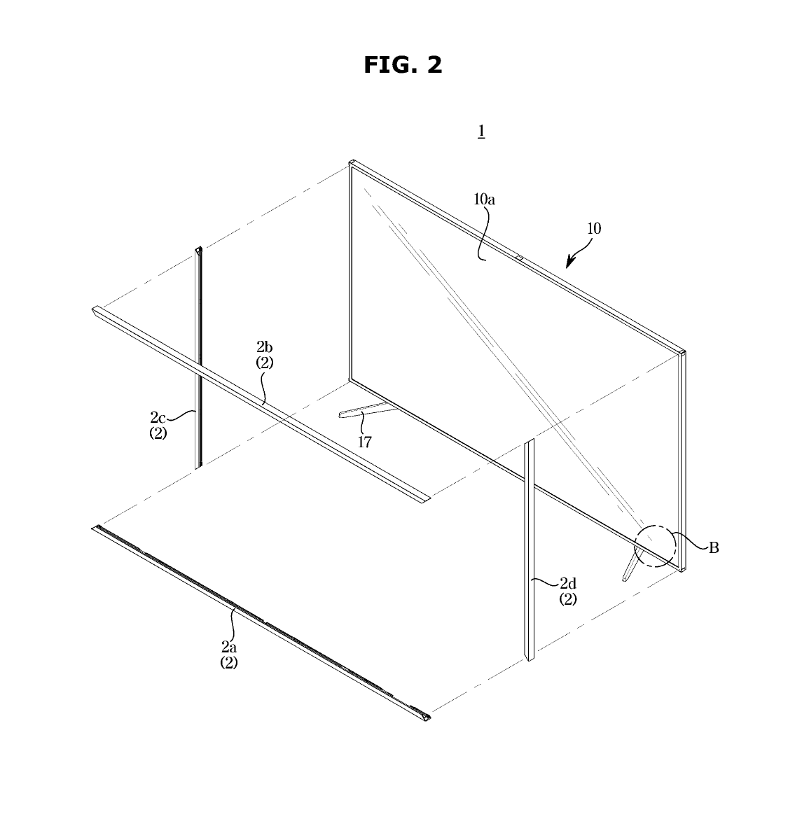

FIG. 1 illustrates a display apparatus according to an embodiment. FIG. 2 illustrates a display apparatus according to an embodiment, with a decorative bezel removed.

The display apparatus 1 may process an image signal received from the outside and visually display the processed image. Hereinafter, an example in which the display apparatus 1 is a television (TV) is described, but the present disclosure is not limited thereto. For example, the display apparatus 1 may be implemented in various forms such as a monitor, a portable multimedia device, a portable communication device, a portable computing device and/or the like, and the forms of the display apparatus 1 are not limited.

In addition, the display apparatus 1 may be a large format display (LFD) installed at a certain location such as on a rooftop of a building or at a bus stop. Here, the certain location is not limited to an outdoor place, and the display apparatus 1 according to an embodiment may be installed in a place in which a large number of people may enter and exit that may be an indoor place such as a subway station, a shopping mall, a movie theater, a company, a store, and/or the like.

The display apparatus 1 may receive a video signal and an audio signal from various content sources, and output a video and an audio respectively corresponding to the video signal and the audio signal. For example, the display apparatus 1 may receive television broadcast content through a broadcast reception antenna and/or a wired cable, receive content from a content reproduction device, and/or receive content from a content providing server of a content provider.

As shown in FIG. 1, the display apparatus 1 may include a main body 10, a screen 10a configured to display an image, and a support 17 provided under the main body 10 to support the main body 10. Referring to FIGS. 1 and 2, the display apparatus 1 may be provided with a decorative bezel (or detachable bezel) 2 detachably coupled to the main body 10.

The main body 10 may form an appearance of the display apparatus 1, and components configured to cause the display apparatus 1 to display an image and/or perform various functions may be provided in the main body 10. The main body 10 shown in FIG. 1 may have a flat plate shape, but the shape of the main body 10 is not limited to the case shown in FIG. 1. For example, the main body 10 may have a curved plate shape.

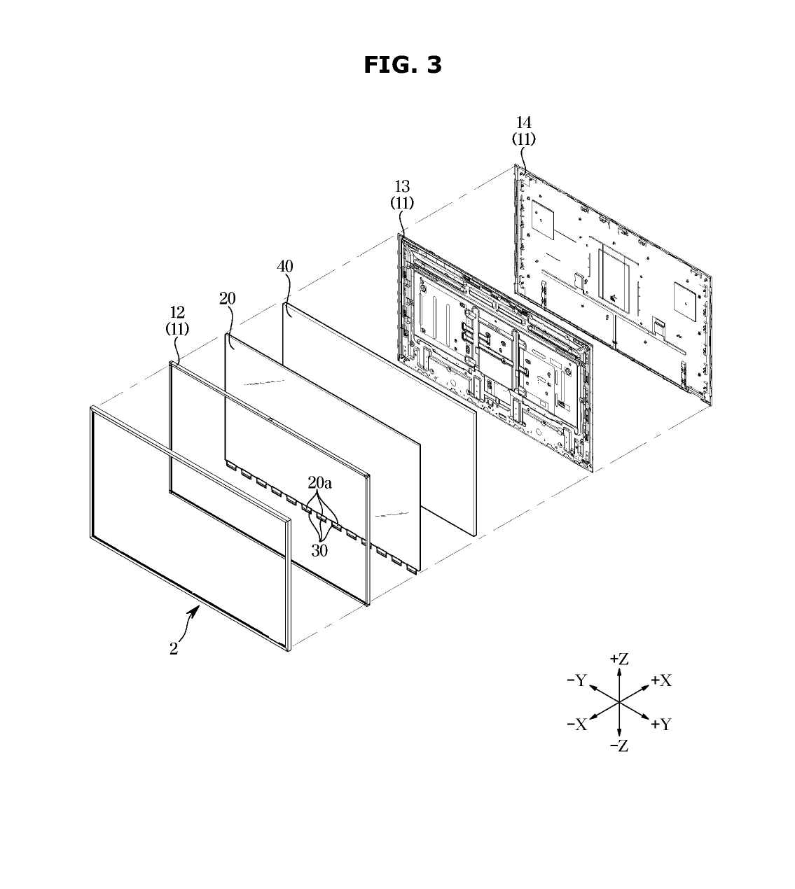

The main body 10 may include a display panel 20 (see e.g., FIG. 3) that provides the screen 10a, and a case 11 (see e.g., FIG. 3) configured to cover an edge and a rear surface of the display panel 20. The case 11 may include a front chassis 12 (see e.g., FIG. 3), a rear chassis 13 (see e.g., FIG. 3), and a rear cover 14 (see e.g., FIG. 3). This will be described in detail later.

The screen 10a may be provided on a front surface of the main body 10, and may display the image. For example, the screen 10a may display a still image or a moving image. Further, the screen 10a may display a two-dimensional flat image or a three-dimensional stereoscopic image using parallax of a user’s eyes.

A plurality of pixels are provided on the screen 10a, and the image displayed on the screen 10a may be generated by light emitted from each of the plurality of pixels. For example, the image may be generated on the screen 10a by combining the light emitted by the plurality of pixels like a mosaic.

Each of the plurality of pixels may emit light of various brightness and colors. For example, each of the plurality of pixels may directly emit light (for example, a light-emitting diode), may be of a non-self-emissive type (for example, a liquid crystal) configured to transmit or block light emitted by a light source, and/or the like.

In order to emit light of various colors, each of the plurality of pixels may include sub-pixels.

The sub-pixels may include a red sub-pixel configured to emit red light, a green sub-pixel configured to emit green light, and a blue sub-pixel configured to emit blue light. For example, the red light may represent light of a wavelength from approximately 620 nm (nanometer, billionths of a meter) to 750 nm, the green light may represent light of a wavelength from approximately 495 nm to 570 nm, and the blue light may represent light of a wavelength from approximately 450 nm to 495 nm.

The light of various brightness and colors may be emitted from each of the plurality of pixels by combination of the red light of the red sub-pixel, the green light of the green sub-pixel, and the blue light of the blue sub-pixel.

The main body 10 may be provided with at least one decorative bezel 2. The decorative bezel 2 may be configured to have various designs and/or patterns according to a user’s preference. The decorative bezel 2 may be detachably mounted to the main body 10 such that a user may mount various decorative bezels 2 to the case 11 as needed.

The decorative bezel 2 may include a lower decorative bezel 2a configured to be mountable to a lower portion of the main body 10, an upper decorative bezel 2b configured to be mountable to an upper portion of the main body 10, a left-end decorative bezel 2c configured to be mountable to a left end portion of the main body 10, and a right-end decorative bezel 2d configured to be mountable to a right end portion of the main body 10.

The support 17 may be installed at a lower portion of the main body 10 to allow the main body 10 to stably maintain its posture, e.g., on a floor surface. Alternatively, the support 17 may be installed on a rear surface of the main body 10 to allow the main body 10 to be firmly fixed to, e.g., a wall surface.

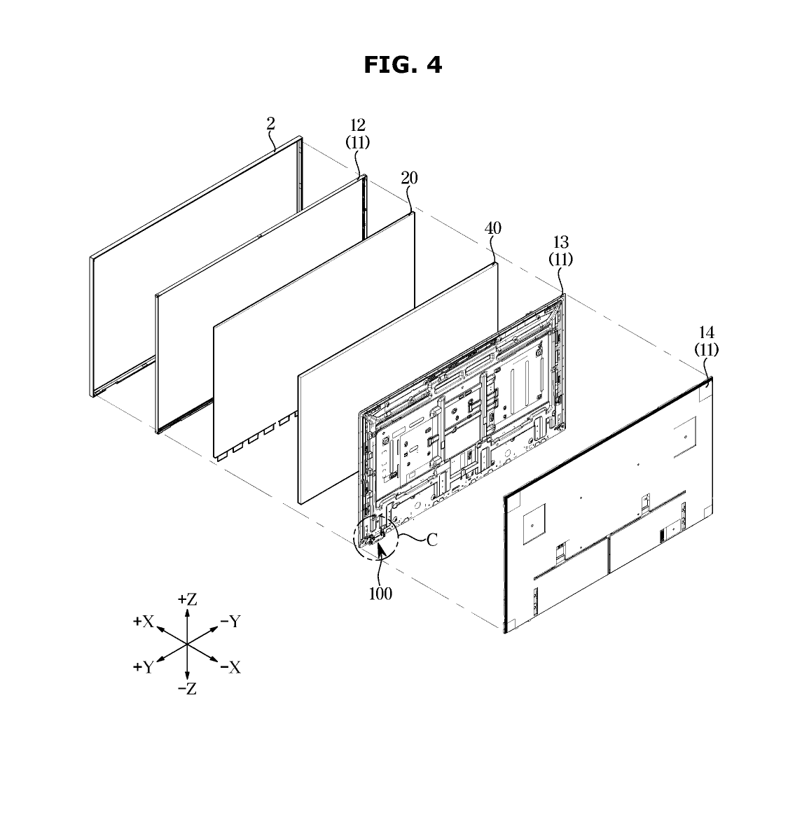

FIG. 3 is an exploded view of the display apparatus according to an embodiment. FIG. 4 is a view of FIG. 3 seen from a different angle

Referring to FIGS. 3 and 4, the display apparatus 1 may include a display panel 20, a light source device 40 configured to provide light to the display panel 20, a front chassis 12 configured to cover a side surface and a front edge of the display panel 20, a rear chassis 13 configured to cover a rear surface of the display panel 20, and a rear cover 14 configured to cover a rear surface of the rear chassis 13. The front chassis 12, the rear chassis 13, and the rear cover 14 may collectively be referred to as a case 11.

According to an embodiment, the display apparatus 1 may include the light source device 40 configured to emit light forward, and the display panel 20 configured to block or transmit the light emitted from the light source device 40.

A cable 20a through which image data is transmitted to the display panel 20 and a display driver integrated circuit 30 (hereinafter, referred to as the “driver IC”) configured to process digital image data and output an analog image signal may be provided on one side of the display panel 20.

The cable 20a may electrically connect between a control assembly and/or a power supply assembly and the driver IC 30 and may also electrically connect between the driver IC 30 and the display panel 20. The cable 20a may include a flexible flat cable, a film cable, and/or the like that may be bendable.

The driver IC 30 may receive image data and power from the control assembly and the power supply assembly through the cable 20a. Further, the driver IC 30 may provide image data and driving current to the display panel 20 through the cable 20a.

Further, the cable 20a and the driver IC 30 may be integrally implemented as a film cable, a chip on film (COF), a tape carrier package (TCP), and/or the like. In other words, the driver IC 30 may be disposed on the cable 20a, but the disclosure is not limited thereto, and for example, the driver IC 30 may be disposed on the display panel 20.

The control assembly may include a control circuit configured to control operations of the display panel 20 and the light source device 40. The control circuit may process image data received from an external content source, transmit the image data to the display panel 20, and transmit dimming data to the light source device 40.

The power assembly may supply power to the display panel 20 and the light source device 40 such that the light source device 40 outputs planar light and the display panel 20 blocks or transmits the light from the light source device 40.

The control assembly and the power supply assembly may be implemented with a printed circuit board and various circuits mounted on the printed circuit board. For example, the power supply assembly may include a power supply circuit, which may include a condenser, a coil, a resistance element, a processor, and/or the like, and a power supply circuit board on which elements of the power supply circuit are mounted. The control assembly may include a control circuit, which may include, for example, a memory, a processor, and/or the like, and a control circuit board on which elements of the control circuit are mounted.

According to an embodiment, the display apparatus 1 may not include a light source device, but may include a display panel that emits light by itself. For example, the display apparatus 1 may include a display panel on which a plurality of organic light emitting diodes (OLEDs) are mounted.

Referring to FIG. 4, the display apparatus 1 may include a sensor device 100. The sensor device 100 may include, for example but not limited to, at least one of an infrared (IR) sensor, an illuminance sensor, a color sensor, a motion sensor, or a microphone. The sensor device 100 may be fixed to the rear chassis 13. The sensor device 100 may be mounted at a lower portion of the rear chassis 13.

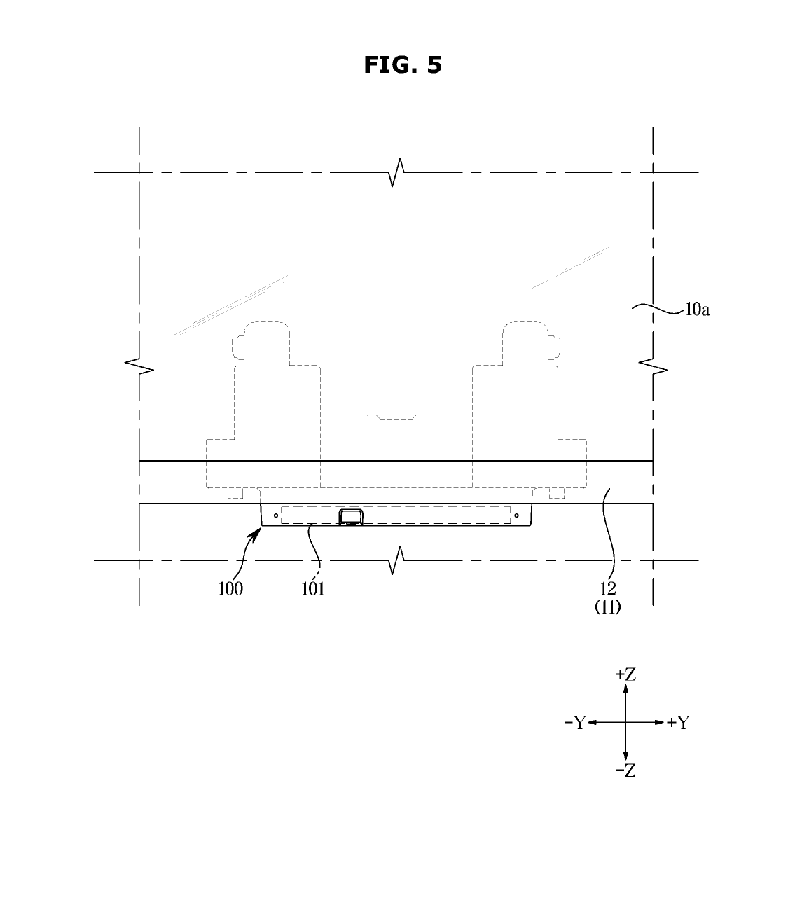

FIG. 5 is an enlarged front view of portion B of FIG. 2.

Referring to FIG. 5, the sensor device 100 may include a sensor accommodating portion 101 in which at least one of an infrared (IR) sensor, an illuminance sensor, a color sensor, a motion sensor, or a microphone is disposed. The sensor accommodating portion 101 may be provided at a lower portion of the sensor device 100.

At least a portion of the sensor device 100 may be configured to protrude outward from the case 11. Specifically, the sensor accommodating portion 101 of the sensor device 100 may be configured to protrude outward of the case 11. As described above, at least one of the infrared sensor, the illuminance sensor, the color sensor, the motion sensor, or the microphone may be disposed in the sensor accommodating portion 101. When the sensor accommodating portion 101 is covered by the case 11, a reception rate of signals transmitted from an input device may decrease, a detection accuracy of ambient brightness and color may deteriorate, a sound reception rate of the microphone may decrease, and/or movement of a user may not be accurately detected. To prevent this, the sensor accommodating portion 101 provided at the lower portion of the sensor device 100 may protrude downward beyond the case 11. The case 11 may refer to a lower end portion of the front chassis 12 covering a lower end of the display panel 20. The term “outward of the case 11” may include “outward of a lower portion of the case 11.”

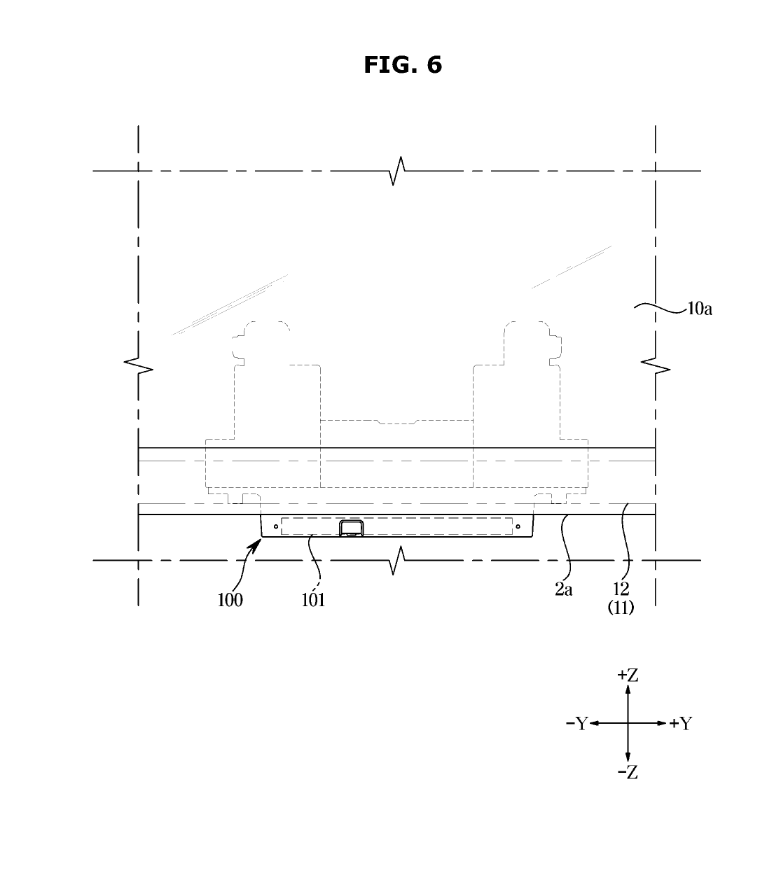

FIG. 6 is an enlarged front view of portion A of FIG. 1.

Referring to FIG. 6, the decorative bezel 2 may be mounted to the case 11. The decorative bezel 2 may have a width in an up-and-down direction (e.g., Z-direction) greater than that of the front chassis 12 of the case 11. As the width of the decorative bezel 2 in the up-and-down direction is greater than that of the front chassis 12, at least a portion of the sensor accommodating portion 101 of the sensor device 100 may be covered by the decorative bezel 2 when the decorative bezel 2 is mounted to the case 11. As described above, since the sensor device 100 is disposed at the lower portion of the case 11, at least a portion of the sensor accommodating portion 101 may be covered by the lower decorative bezel 2a. Hereinafter, for convenience of description, the lower decorative bezel 2a will be referred to simply as the decorative bezel 2a.

When the sensor accommodating portion 101 of the sensor device 100 is covered by the decorative bezel 2a, a reception rate and/or a detection rate of the sensors disposed in the sensor accommodating portion 101 may be reduced. To prevent this, at least a portion of the sensor device 100 according to the present disclosure may be configured to protrude outward of the decorative bezel 2a when the decorative bezel 2a is mounted to the case 11. More specifically, the sensor accommodating portion 101 of the sensor device 100 may be configured to protrude outward of the decorative bezel 2a by being moved downward when the decorative bezel 2a is mounted to the case 11. A structure of the sensor device 100 configured to move the sensor accommodating portion 101 downward when the decorative bezel 2a is mounted to the case 11 will be described in detail later.

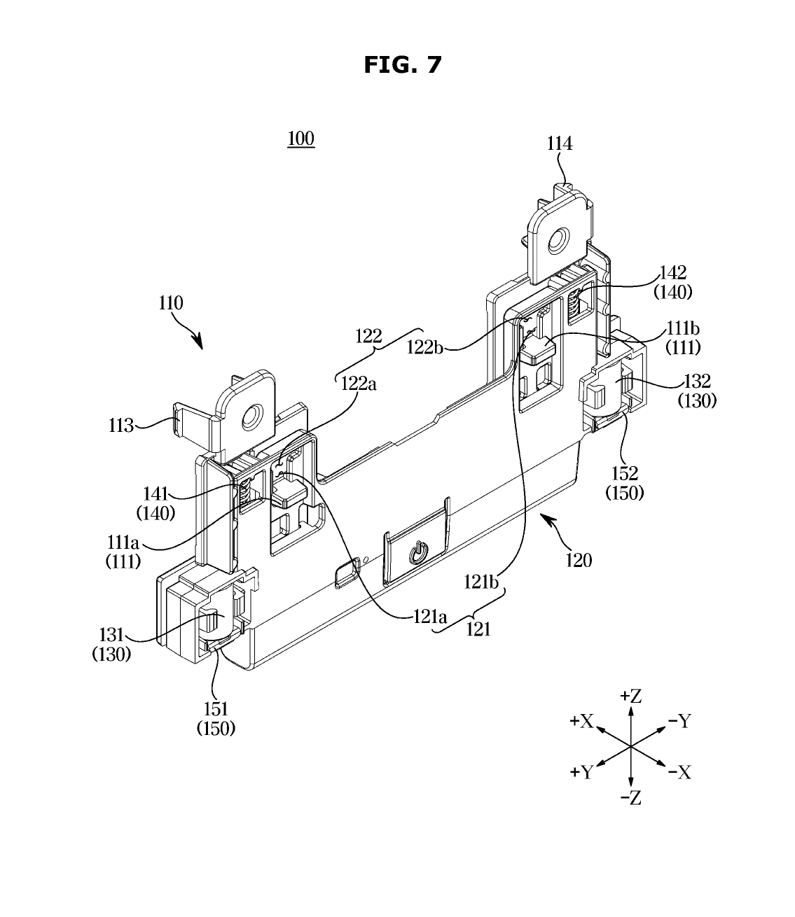

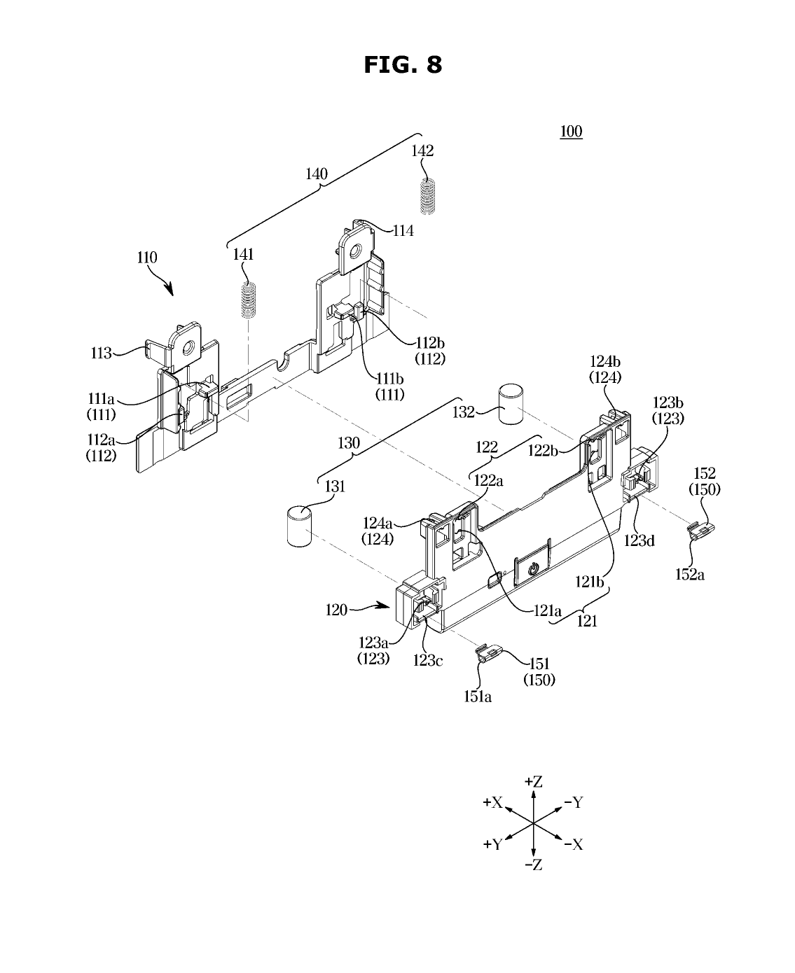

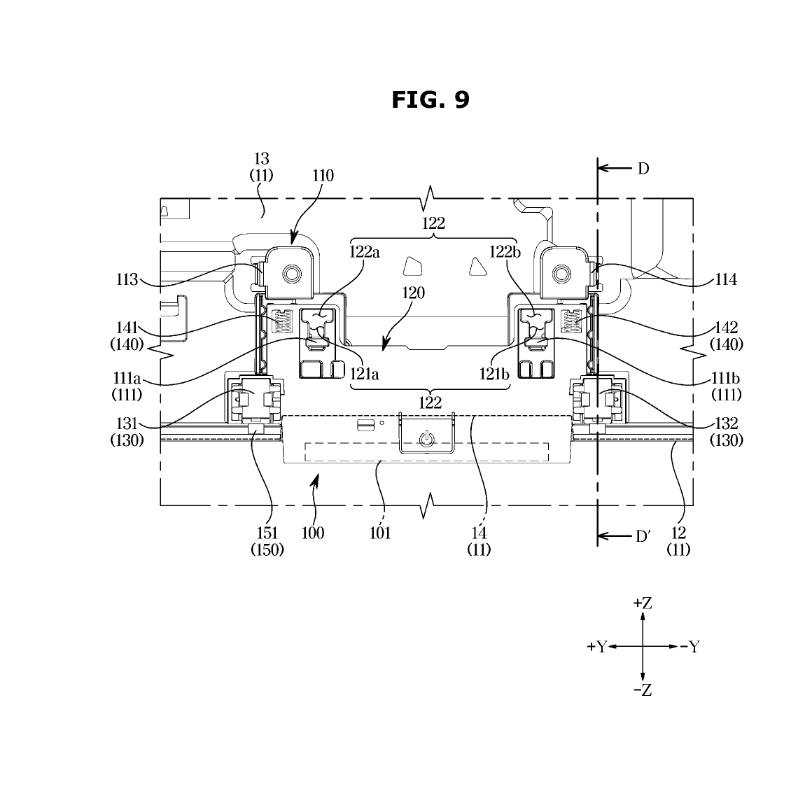

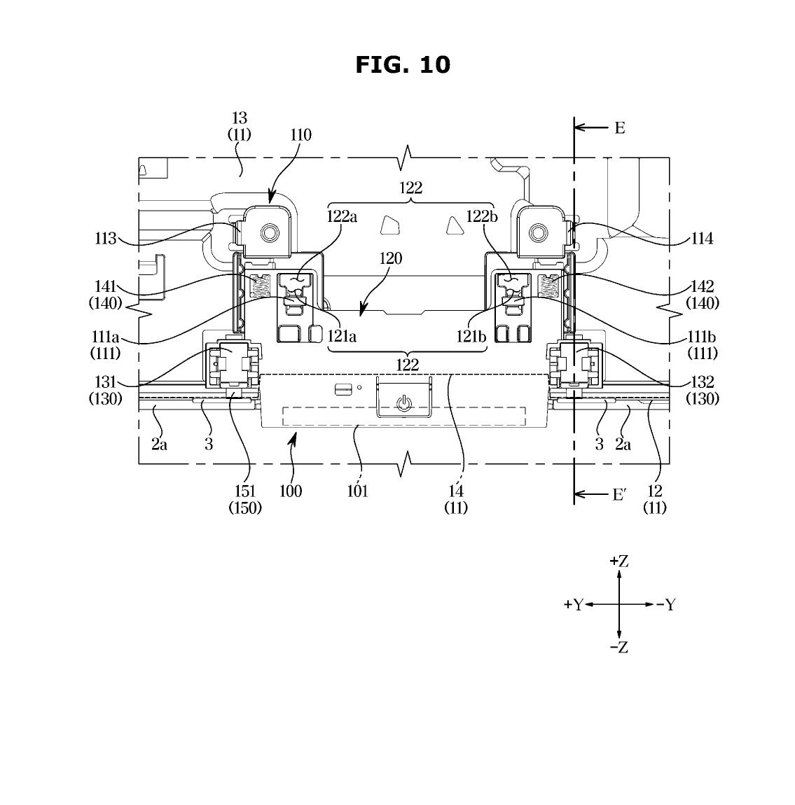

FIG. 7 is an enlarged view of a sensor device shown at portion C of FIG. 4. FIG. 8 is an exploded view of the sensor device of FIG. 7. FIG. 9 is an enlarged view of a portion of a rear surface of a display apparatus according to an embodiment, illustrating a moving member of a sensor device positioned at a first position. FIG. 10 is an enlarged view of a portion of a rear surface of a display apparatus according to an embodiment, illustrating a moving member of a sensor device positioned at a second position.

Referring to FIGS. 7 and 8, a sensor device 100 according to an embodiment may include a fixing member 110 configured to be fixed to a case 11, and a moving member 120 configured to be movably provided with respect to the fixing member 110.

The fixing member 110 may be fixed inside the case 11. More specifically, the fixing member 110 may be fixed to a rear chassis 13. By insertion of a first coupling protrusion 113 and a second coupling protrusion 114 of the fixing member 110 into coupling holes of the rear chassis 13, the fixing member 110 may be mounted to and fixed to the rear chassis 13. The fixing member 110 may be mounted to a lower portion of a rear surface of the rear chassis 13.

The moving member 120 may be coupled to the fixing member 110. The moving member 120 may be coupled to the fixing member 110 to be movable in the up-and-down direction with respect to the fixing member 110. The sensor accommodating portion 101 may be provided in the moving member 120. At least one of the infrared (IR) sensor, the illuminance sensor, the color sensor, the motion sensor, and the microphone may be disposed in the sensor accommodating portion 101 of the moving member 120. The sensor accommodating portion 101 may be provided at a lower portion (e.g., lower end) of the moving member 120.

When the decorative bezel 2a is separated from the case 11, the moving member 120 may be positioned at a first position. When the decorative bezel 2a is mounted to the case 11, the moving member 120 may be positioned at a second position. The moving member 120 may be moved from the first position in a direction protruding outward of the case 11 to be positioned at the second position.

According to an embodiment, the second position may be set lower than the first position. In other words, when the decorative bezel 2a is mounted to the case 11, the moving member 120 may move downward from the first position and be positioned at the second position.

When the moving member 120 is positioned at the second position, the sensor accommodating portion 101 may be configured to protrude outward beyond the decorative bezel 2a. When the moving member 120 is positioned at the second position, the sensor accommodating portion 101 may protrude downward beyond the decorative bezel 2a. Accordingly, when the moving member 120 is positioned at the second position, the sensor accommodating portion 101 may not be covered by the decorative bezel 2a.

The sensor device 100 may include a first magnet 130 mounted to the moving member 120 to move together with the moving member 120, and a second magnet 3 (see e.g., FIG. 10) mounted to the decorative bezel 2a to be positioned adjacent to the first magnet 130.

The first magnet 130 may have a substantially cylindrical shape. The first magnet 130 may include a pair of first magnets 131and132 provided at a first side and a second side, facing the first side, of the moving member 120. The pair of first magnets 131 and 132 may be received in a pair of magnet accommodating portions 123a and 123b respectively provided at the first side and the second side of the moving member 120. Since the pair of first magnets 131 and 132 are provided at the first side and the second side of the moving member 120, the moving member 120 may move downward without tilting to one side, by a magnetic force generated by the pair of first magnets 131and132.

Referring to FIGS. 9 and 10, the decorative bezel 2a may include the second magnet 3. The decorative bezel 2a may include the second magnet 3 that is mounted to the decorative bezel 2a to be positioned adjacent to the first magnet 130 when the decorative bezel 2a is mounted to the case 11. The second magnet 3 may be provided in a position and a number corresponding to the first magnet 130. When the first magnet 130 is provided as a pair, the second magnet 3 may also be provided as a pair.

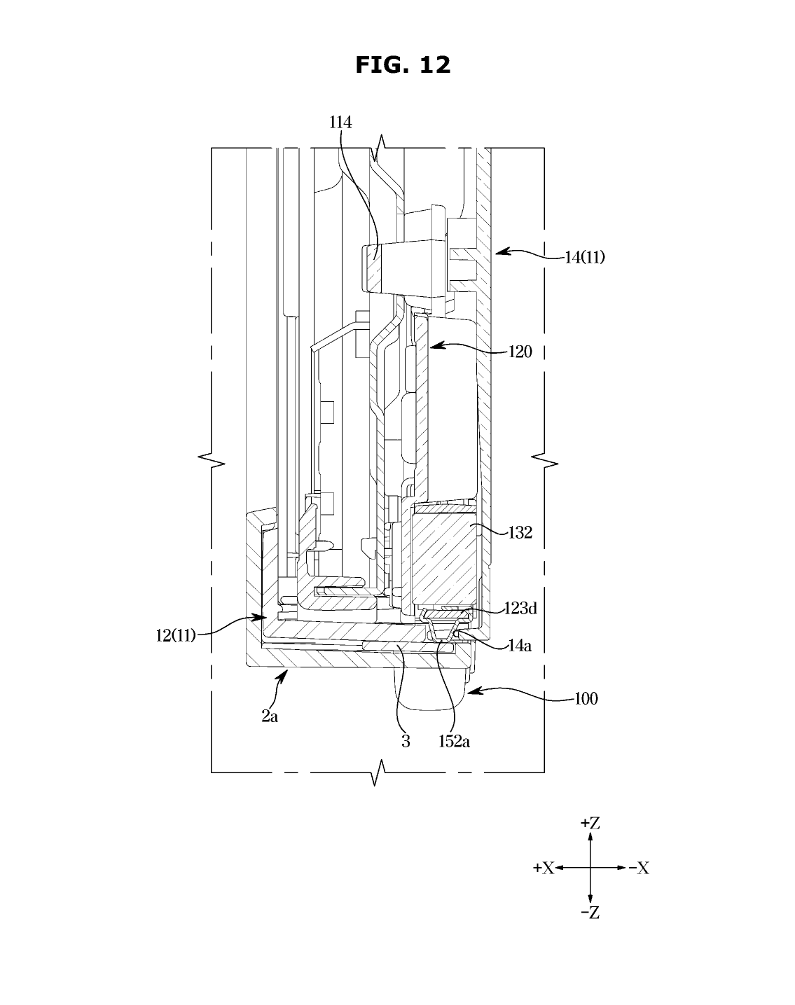

The second magnet 3 may be formed in a plate shape. An upper surface of the second magnet 3 may be arranged to face a lower surface of the case 11. Specifically, the upper surface of the second magnet 3 may be arranged to face a lower surface of the front chassis 12. For example, when the decorative bezel 2a is mounted to the case 11, the upper surface of the second magnet 3 may come into contact with the lower surface of the front chassis 12 (see e.g., FIG. 12).

The sensor device 100 may include an elastic member 140 configured to press the moving member 120 coupled to the fixing member 110 toward the first position. The elastic member 140 may bias the moving member 120 toward the first position.

A lower end of the elastic member 140 may be supported by the fixing member 110, and an upper end of the elastic member 140 may be supported by the moving member 120. When the elastic member 140 is accommodated between the fixing member 110 and the moving member 120 such that a lower end and an upper end of the elastic member 140 are supported by the fixing member 110 and the moving member 120, respectively, the elastic member 140 may be configured to be compressed in the up-and-down direction. An elastic force accumulated as the elastic member 140 is compressed may bias the moving member 120 for the moving member 120 to move upward.

Referring to FIG. 8, the elastic member 140 may include a first elastic member 141 provided at a first side of the fixing member 110 and the first side of the moving member 120, and a second elastic member 142 provided at a second side of the fixing member 110 and the second side of the moving member 120, the first side and the second side of the fixing member 110 facing each other. However, the present disclosure is not limited thereto, and a number and a position(s) of the elastic member 140 may be varied.

The fixing member 110 may include a first fixing portion 112 configured to support the lower end of the elastic member 140. The first fixing portion 112 may include a pair of first fixing portions 112a and 112b respectively supporting lower ends of the pair of elastic members 141 and 142.

The moving member 120 may include a second fixing portion 124 configured to support the upper end of the elastic member 140. The second fixing portion 124 may include a pair of second fixing portions 124a and 124b respectively supporting upper ends of the pair of elastic members 141 and 142.

The moving member 120 may include a guide hole 121 extending along a moving direction of the moving member 120. As described above, since the moving member 120 is configured to be movable in the up-and-down direction, the guide hole 121 may extend along the up-and-down direction (Z-direction).

The fixing member 110 may include a guide protrusion 111 configured to be inserted into the guide hole 121 of the moving member 120 to guide the moving member 120 to move between the first position and the second position. By insertion of the guide protrusion 111 into the guide hole 121, the moving member 120 may not be separated from the fixing member 110. For this purpose, at least a portion of the guide protrusion 111 may have a width larger than a width of the guide hole 121. A portion of the guide protrusion 111 having a larger width may be referred to as a head portion of the guide protrusion 111.

The moving member 120 may include an insertion hole 122 having a width larger than that of the head portion of the guide protrusion 111 such that the head portion of the guide protrusion 111 may be inserted. The insertion hole 122 may be connected to an upper end of the guide hole 121. In other words, the insertion hole 122 may be provided above the guide hole 121 and connected to the guide hole 121. As the guide protrusion 111 passing through the insertion hole 122 moves downward, the guide protrusion 111 may be inserted into the guide hole 121.

For stable movement of the moving member 120 relative to the fixing member 110, the guide protrusion 111 may include a pair of guide protrusions 111a and 111b respectively provided at the first side and the second side of the fixing member 110. The moving member 120 may include a pair of guide holes 121a and 121b and a pair of insertion holes 122a and 122b corresponding to the pair of guide protrusions 111a and 111b.

According to an embodiment, the sensor device 100 may further include a magnetic reinforcement member 150 disposed between the first magnet 130 and the second magnet 3 to reinforce a magnetic attraction between the first magnet 130 and the second magnet 3.

The magnetic reinforcement member 150 may be provided to be in contact with the first magnet 130. The magnetic reinforcement member 150 may include a first magnetic reinforcement member 151 and a second magnetic reinforcement member 152 respectively provided to contact the pair of first magnets 131 and 132.

The magnetic reinforcement member 150 may include a ferromagnetic material that may be magnetized by being in contact with the first magnet 130. The magnetic reinforcement member 150 may include a protrusion portion 151a, 152a that may be configured to contact a lower surface of the first magnet 130 and protrude downward. The protrusion portions 151a and 152a of the magnetic reinforcement member 150 may reduce a distance between the magnetic reinforcement member 150 and the second magnet 3. The magnetic reinforcement member 150 may substantially serve to reduce the distance between the first magnet 130 and the second magnet 3. By including the magnetic reinforcement member 150, the magnetic attraction between the first magnet 130 and the second magnet 3 may be reinforced. As the magnetic attraction between the first magnet 130 and the second magnet 3 is reinforced, the moving member 120 may be positioned at the second position as designed when the decorative bezel 2a is mounted to the case 11. When the magnetic attraction between the first magnet 130 and the second magnet 3 is insufficient, the moving member 120 may stop between the first position and the second position without reaching the second position.

The magnetic reinforcement member 150 may be detachably mounted to the moving member 120. The magnetic reinforcement member 150 may be mounted to a magnet support 123c, 123d of the moving member 120 provided to support a lower surface of the first magnet 130. For example, the magnetic reinforcement member 150 may be snap-fitted to the magnet support 123c, 123d of the moving member 120. By coupling the magnetic reinforcement member 150 to the magnet support 123c, 123d provided to support the lower surface of the first magnet 130, the magnetic reinforcement member 150 may naturally contact the lower surface of the first magnet 130. In other words, the magnetic reinforcement member 150 may contact and support the lower surface of the first magnet 130.

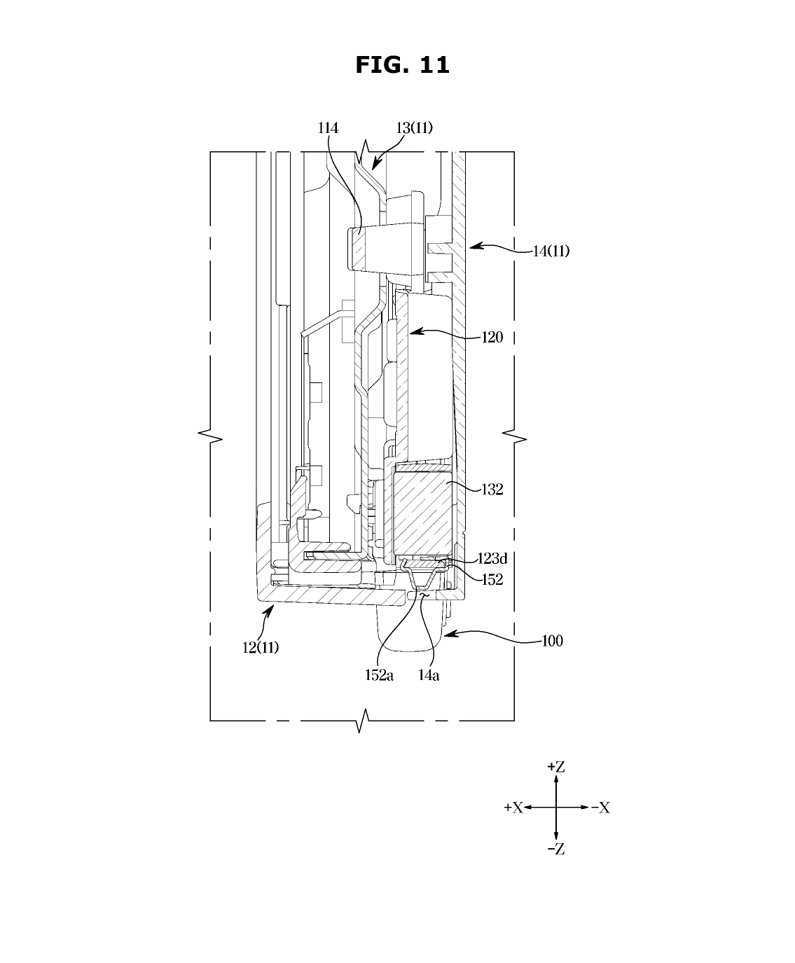

FIG. 11 is a cross-sectional view taken along line D-D’ of FIG. 9. FIG. 12 is a cross-sectional view taken along line E-E’ of FIG. 10.

Referring to FIGS. 9 to 12, a process and a structure in which the moving member 120 moves from a first position to a second position when the decorative bezel 2a is mounted to the case 11 will be described in detail. In FIGS. 9 and 10, the sensor device 100 is viewed from the rear of the display apparatus 1, and the rear cover 14 is illustrated transparently.

Referring to FIG. 9, when the decorative bezel 2a is separated from the case 11, the moving member 120 may be positioned at the first position. As described above, since a width of the decorative bezel 2a in an up-and-down direction is greater than that of the front chassis 12, assuming that the decorative bezel 2a is mounted to the front chassis 12 and the moving member 120 is positioned at the first position, the sensor accommodating portion 101 of the sensor device 100 may be covered by the decorative bezel 2a.

Referring to FIG. 10, the moving member 120 may move downward and be positioned at the second position due to a magnetic attraction between the first magnet 130 of the sensor device 100 and the second magnet 3 of the decorative bezel 2a. The second position may be set lower than the first position.

When the moving member 120 moves downward from the first position and is positioned at the second position, the sensor accommodating portion 101 of the sensor device 100 may protrude outward beyond the decorative bezel 2a. As the sensor accommodating portion 101 protrudes outward beyond the decorative bezel 2a, one or more sensors such as an infrared (IR) sensor, an illuminance sensor, a color sensor, a motion sensor, and a microphone disposed therein may operate normally without being substantially affected by the decorative bezel 2a and/or the case 11.

When the moving member 120 moves from the first position to the second position, the guide protrusion 111 of the fixing member 110 may move relatively along the guide hole 121 of the moving member 120. Since the fixing member 110 is fixed to the rear chassis 13, it is not the guide protrusion 111 that moves, but rather the guide hole 121 that moves, and the guide protrusion 111 may guide the movement of the guide hole 121.

When the decorative bezel 2a is detached or separated from the case 11, the elastic member 140 may press the moving member 120 for the moving member 120 to move toward the first position as described above. In other words, the elastic member 140 may bias the moving member 120 toward the first position. By the elastic force of the elastic member 140, when the decorative bezel 2a is not mounted to the case 11 or is separated from the case 11, the sensor accommodating portion 101 of the sensor device 100 may be prevented from excessively protruding outward of the case 11. In an embodiment, the sensor accommodating portion 101 may protrude outward of the case 11 only to such an extent that sensors and microphones disposed therein may operate normally. Thus, when the decorative bezel 2a is not mounted to the case 11, the elastic member 140 may allow the moving member 120 to be positioned at the first position to prevent the sensor accommodating portion 101 from excessively protruding outward of the case 11.

When the decorative bezel 2a is mounted to the case 11, a magnetic attraction between the first magnet 130 and the second magnet 3 need to be greater than the elastic force of the elastic member 140. When the elastic force of the elastic member 140 is greater than the magnetic attraction between the first magnet 130 and the second magnet 3, the moving member 120 may remain at the first position or be positioned between the first position and the second position.

According to an embodiment, the sensor device 100 may include the magnetic reinforcement member 150 for reinforcing the magnetic attraction between the first magnet 130 and the second magnet 3. The magnetic reinforcement member 150 may be a magnetic material that may be magnetized by contact with the first magnet 130. For example, the magnetic reinforcement member 150 may be a ferromagnetic metal member.

The magnetic reinforcement member 150 may be provided to contact the first magnet 130. The magnetic reinforcement member 150 may include protrusion portions 151a and 152a protruding toward the second magnet 3. The magnetic reinforcement member 150 may be snap-fitted to the magnet support 123c, 123d of the moving member 120 provided to support a lower surface of the first magnet 130.

Referring to FIGS. 11 and 12, the rear cover 14 may be provided to cover a rear surface of the rear chassis 13. As described above, the rear chassis 13 may be provided to cover a rear surface of the display panel 20. By covering the rear surface of the rear chassis 13, the rear cover 14 may provide a rear surface of the display apparatus 1.

The fixing member 110 of the sensor device 100 may be coupled to the rear chassis 13. By coupling the fixing member 110 to the rear chassis 13, the fixing member 110 may be fixed. For example, the fixing member 110 may be coupled to the rear chassis 13 by insertion of the first coupling protrusion 113 and the second coupling protrusion 114 of the fixing member 110 into coupling holes provided on the rear chassis 13.

The rear cover 14 may be provided to cover at least a portion of the sensor device 100. More specifically, the rear cover 14 may be provided to surround at least a portion of the first magnet 130 and the magnetic reinforcing member 150 of the sensor device 100. The rear cover 14 may be provided to cover at least a portion of a rear surface, a side surface, an upper surface, and a lower surface of the first magnet 130 and the magnetic reinforcement member 150.

According to an embodiment, the rear cover 14 may include a cover hole 14a configured such that at least a portion of the protrusion portion 151a, 152a of the magnetic reinforcement member 150 is inserted therein when the moving member 120 moves from the first position to the second position. As illustrated in FIGS. 11 and 12, the cover hole 14a may be positioned below the magnetic reinforcement member 150 when the moving member 120 is positioned at the first position. When the moving member 120 moves to the second position, the protrusion portion 151a, 152a of the magnetic reinforcement member 150 may pass through the cover hole 14a and come into contact with the second magnet 3. By the magnetic reinforcement member 150 coming into contact with the second magnet 3, the downward movement of the moving member 120 may be stopped. By the magnetic reinforcement member 150 coming into contact with the second magnet 3, the moving member 120 moving downward may stop at the second position. However, the present disclosure is not limited thereto. A moving range of the moving member 120 may be set by using the guide hole 121. Further, the rear cover 14 may be provided without a cover hole. In this case, the downward movement of the moving member 120 may be stopped by the magnetic reinforcement member 150 coming into contact with the rear cover 14.

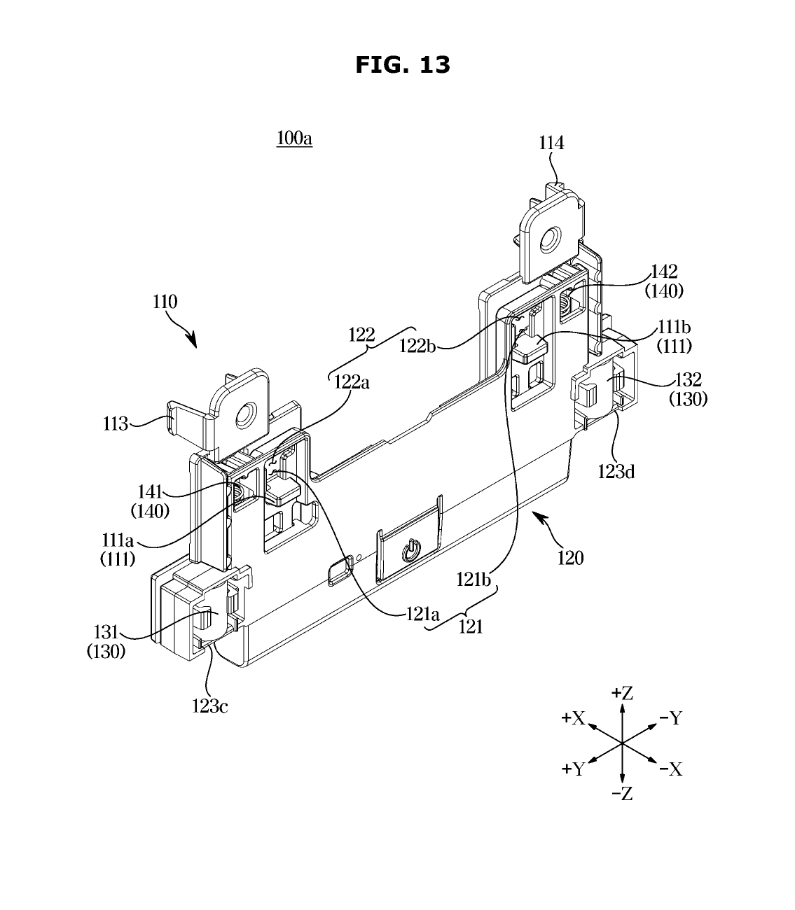

FIG. 13 illustrates a sensor device of a display apparatus according to an embodiment.

A sensor device 100a of a display apparatus 1 according to an embodiment may not include a magnetic reinforcement member. The remaining configurations, except for the magnetic reinforcement member, may be the same as or similar to those of the sensor device 100 described with reference to FIGS. 1 to 12, and thus, the same description will be omitted.

Referring to FIG. 13, a lower surface of a first magnet 130 may be supported by a magnet support 123c, 123d. When a decorative bezel 2a is mounted to a case 11, a moving member 120 of the sensor device 100a may move to the second position by the magnetic attraction between the first magnet 130 of the sensor device 100a and a second magnet 3 of the decorative bezel 2a.

According to an embodiment, the decorative bezel 2a may be provided with a metal member instead of a magnet. The metal member may include a ferromagnetic material. The metal member may have a plate shape to be mountable to the decorative bezel 2a. When the decorative bezel 2a is mounted to the case 11, the moving member 120 may move from the first position to the second position by the magnetic attraction between the ferromagnetic metal member and the first magnet 130. In an embodiment, the decorative bezel 2a may be provided with both the metal member and the magnet.

According to an embodiment, the moving member 120 may be provided with a metal member instead of a magnet. The metal member may include a ferromagnetic material. The metal member may have a cylindrical shape to be mountable to a magnet accommodating portion of the moving member 120. The decorative bezel 2a may include a second magnet (e.g., 3 in FIG. 10) that attracts the metal member by a magnetic force. When the decorative bezel 2a is mounted to the case 11, the moving member 120 may move from the first position to the second position by the magnetic attraction between the metal member accommodated in the moving member 120 and the second magnet of the decorative bezel 2a. In an embodiment, the moving member 120 may be provided with both the metal member and the magnet.

According to an embodiment, a display apparatus may include: a case; a display panel mounted to the case; and a sensor device including a fixing member fixed inside the case and a moving member movably provided with respect to the fixing member and on which at least one sensor is mounted. When the detachable bezel is detached from the case, the moving member is positioned at a first position, and when the detachable bezel is mounted to the case, the moving member is positioned at a second position by being moved by a magnetic force.

According to an embodiment, the moving member may be positioned at the second position by moving from the first position in a direction protruding outward from the case.

According to an embodiment, when the moving member is positioned at the second position, the at least one sensor may be configured to protrude outward from (e.g., beyond) the detachable bezel.

According to an embodiment, the sensor device may include: a first magnet mounted to the moving member and configured to move together with the moving member by a magnetic force generated by the first magnet and a second magnet included in the detachable bezel.

According to an embodiment, a second magnet may be mounted to the detachable bezel and the second magnet may have a plate shape.

According to an embodiment, an upper surface of the second magnet may face a lower surface of the case.

According to an embodiment, the sensor device may further include an elastic member configured to press the moving member to move toward the first position when the detachable bezel is detached from the case.

According to an embodiment, the moving member may include a guide hole extending along a moving direction of the moving member.

According to an embodiment, the fixing member may include a guide protrusion inserted into the guide hole and configured to guide movement of the moving member between the first position and the second position.

According to an embodiment, the sensor device may further include a magnetic reinforcement member disposed between the first magnet and the second magnet and configured to contact the first magnet to reinforce a magnetic attraction between the first magnet and the second magnet.

According to an embodiment, the magnetic reinforcement member may include a protrusion portion protruding toward the second magnet.

According to an embodiment, the display apparatus may further include a rear cover configured to cover a rear surface of the display panel, the rear cover configured to surround at least a portion of the first magnet and the magnetic reinforcement member.

According to an embodiment, the rear cover may include a cover hole into which at least a portion of the protrusion portion is inserted when the moving member moves to the second position.

According to an embodiment, the sensor device may include a pair of first magnets disposed at a first side and a second side, facing the first side, of the moving member.

According to an embodiment, the sensor device may include a pair of second magnets mounted to the detachable bezel to be positioned adjacent to the pair of first magnets, respectively, while the detachable bezel is mounted to the case.

According to an embodiment, the sensor device may be disposed at a lower end portion of the case. The moving member may be movably provided in an up-and-down direction with respect to the fixing member.

According to an embodiment, the second position may be lower than the first position in the up-and-down direction.

According to an embodiment, the sensor device may include a magnet mounted to the moving member and configured to move together with the moving member by a magnetic force generated between the magnet and a metal member included in the detachable bezel.

According to an embodiment, the sensor device may include a metal member mounted to the moving member and configured to move together with the moving member by a magnetic force generated between the metal member and a magnet included in the detachable bezel.

According to an embodiment, a sensor device may be included in a display apparatus including a display panel, the sensor device including: a moving member on which at least one sensor is mounted; and an elastic member configured to bias the moving member to a first position in a direction toward the display panel, wherein the moving member includes at least one of a magnet or metal and is configured to move between the first position and a second position away from the display panel by a magnetic force generated from the at least one of the magnet or metal and an elastic force of the elastic member.

According to an embodiment, the moving member may be configured to move to the second position based on a detachable bezel being mounted to the display apparatus.

According to an embodiment, when the moving member is at the second position, the at least one sensor may be configured to protrude outward of the detachable bezel.

According to an embodiment, the sensor device may further include a fixing member fixed at a portion of the display apparatus and configured to guide movement of the moving member between the first position and the second position.

According to an embodiment, a sensor device may be included in a display apparatus including a display panel, the sensor device including: a fixing member fixed at a portion of the display apparatus; and a moving member on which at least one sensor is mounted and configured to move with respect to the fixing member by a magnetic force, the moving member comprising at least one of a magnet or metal, wherein the moving member is configured to, when a detachable bezel is mounted to the display apparatus, move in a direction away from the display panel such that the at least one sensor protrudes from the detachable bezel.

According to an aspect of an example embodiment of the present disclosure, a display apparatus capable of receiving signals from an input device, detecting ambient brightness and color, and detecting user movement even when a decorative bezel is mounted may be provided.

According to an aspect of an example embodiment of the present disclosure, a sensor device capable of automatically changing a position of a sensor without a separate operation when a decorative bezel is mounted, and a display apparatus including the same may be provided.

According to an aspect of an example embodiment of the present disclosure, a sensor device capable of automatically changing a position of a sensor using magnetic force of a magnet when a decorative bezel is mounted, and a display apparatus including the same may be provided.

Although example embodiments of the present disclosure have been described with reference to the accompanying drawings, those skilled in the art will appreciate that the inventive concepts may be embodied in different forms without departing from the scope and spirit of the disclosure, and should not be construed as limited to the embodiments set forth herein.

What is claimed is :

1. A display apparatus comprising:
a case;
a display panel mounted to the case; and
a sensor device including a fixing member fixed inside the case and a moving member movably provided with respect to the fixing member and on which at least one sensor is mounted,
wherein when a detachable bezel is detached from the case, the moving member is positioned at a first position, and when the detachable bezel is mounted to the case, the moving member is positioned at a second position by being moved by a magnetic force.

2. The display apparatus of claim 1, wherein the moving member is positioned at the second position by moving from the first position in a direction protruding outward from the case.

3. The display apparatus of claim 1, wherein when the moving member is positioned at the second position, the at least one sensor is configured to protrude outward of the detachable bezel.

4. The display apparatus of claim 1, wherein the sensor device includes:
a first magnet mounted to the moving member and configured to move together with the moving member by a magnetic force generated by the first magnet and a second magnet included in the detachable bezel.

5. The display apparatus of claim 4, wherein the sensor device further includes an elastic member configured to press the moving member to move toward the first position when the detachable bezel is detached from the case.

6. The display apparatus of claim 4, wherein the moving member includes a guide hole extending along a moving direction of the moving member.

7. The display apparatus of claim 6, wherein the fixing member includes a guide protrusion inserted into the guide hole and configured to guide movement of the moving member between the first position and the second position.

8. The display apparatus of claim 4, wherein the sensor device further includes a magnetic reinforcement member disposed between the first magnet and the second magnet and configured to contact the first magnet to reinforce a magnetic attraction between the first magnet and the second magnet.

9. The display apparatus of claim 8, wherein the magnetic reinforcement member includes a protrusion portion protruding toward the second magnet.

10. The display apparatus of claim 9, further comprising a rear cover configured to cover a rear surface of the display panel, the rear cover configured to surround at least a portion of the first magnet and the magnetic reinforcement member,
wherein the rear cover includes a cover hole into which at least a portion of the protrusion portion is inserted when the moving member moves to the second position.

11. The display apparatus of claim 4, wherein the sensor device includes:
a pair of first magnets disposed at a first side and a second side, facing the first side, of the moving member; and
a pair of second magnets mounted to the detachable bezel to be positioned adjacent to the pair of first magnets, respectively, while the detachable bezel is mounted to the case.

12. The display apparatus of claim 1, wherein the sensor device is disposed at a lower end portion of the case, and
wherein the moving member is movably provided in an up-and-down direction with respect to the fixing member.

13. The display apparatus of claim 12, wherein the second position is lower than the first position in the up-and-down direction.

14. The display apparatus of claim 1, wherein the sensor device includes:
a magnet mounted to the moving member and configured to move together with the moving member by a magnetic force generated between the magnet and a metal member included in the detachable bezel.

15. The display apparatus of claim 1, wherein the sensor device includes:
a metal member mounted to the moving member and configured to move together with the moving member by a magnetic force generated between the metal member and a magnet included in the detachable bezel.

16. A sensor device included in a display apparatus comprising a display panel, the sensor device comprising: a moving member on which at least one sensor is mounted; and
an elastic member configured to bias the moving member to a first position in a direction toward the display panel,
wherein the moving member comprises at least one of a magnet or metal and is configured to move between the first position and a second position away from the display panel by a magnetic force generated from the at least one of the magnet or metal and an elastic force of the elastic member.

17. The sensor device of claim 16, wherein the moving member is configured to move to the second position based on a detachable bezel being mounted to the display apparatus.

18. The sensor device of claim 17, wherein when the moving member is at the second position, the at least one sensor is configured to protrude outward of the detachable bezel.

19. The sensor device of claim 16, further comprising a fixing member fixed at a portion of the display apparatus and configured to guide movement of the moving member between the first position and the second position.

20. A sensor device included in a display apparatus comprising a display panel, the sensor device comprising:
a fixing member fixed at a portion of the display apparatus; and
a moving member on which at least one sensor is mounted and configured to move with respect to the fixing member by a magnetic force, the moving member comprising at least one of a magnet or metal,
wherein the moving member is configured to, when a detachable bezel is mounted to the display apparatus, move in a direction away from the display panel such that the at least one sensor protrudes from the detachable bezel.
